(19) United States
(12) Patent Application Publication
(10) Pub. No.: US 2008/0169500 A1
(43) Pub. Date: Jul. 17, 2008

(54) LOW VOLTAGE NON-VOLATILE MEMORY CELL WITH SHARED INJECTOR FOR FLOATING GATE

(75) Inventor: Bohumil Lojek, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/623,662

(22) Filed: Jan. 16, 2007

(51) Int. Cl. H01L 29/788

(52) U.S. Cl. 257/318; 257/E29.3

(57) ABSTRACT

A non-volatile transistor memory array having memory cells, each with a control transistor and a floating gate memory transistor. The cells are arranged in symmetric quadrants with active regions appearing as tic-tac-toe style strips having a central shared drain erase region. Within the drain erase region is an avalanche diode that has overlying regions of four floating gates of the memory transistors and serving to supply erase current of holes and electrons to addressed floating gates. The cells have four voltage lines or contacts, including a wordline and a bitline, a common source line and a substrate contact that are used both for addressing and for controlling distributed device capacitance in a manner that treats the floating gate as one plate of a virtual capacitor, the other plate being distributed device capacitance in the control transistor, and the memory transistor including the four voltage lines or contacts.

### TECHNICAL FIELD

The invention relates to semiconductor memories and, more particularly, to non-volatile semiconductor memory arrays.

### BACKGROUND ART

In order to reduce manufacturing expense for semiconductor non-volatile memory arrays, some manufacturers have attempted to simplify memory cell construction by using a single polysilicon, i.e., “poly”, layer rather than two or more poly layers. This is particularly challenging in NOR memory arrays consisting of a select or control transistor in series with a memory transistor, both transistors comprising a single memory cell, usually built in a single active area.

In programming and erasing non-volatile memory transistors, it is quite typical to apply a high voltage, i.e. a voltage substantially greater than 5 volts. Voltages of 12-15 volts, or more, are not uncommon for programming and erasing a floating gate of a non-volatile memory transistor. Sophisticated charge pumps are used to step up lower voltages to required high voltages.

One solution in avoiding high voltages is to use capacitive coupling of a floating gate to the substrate and a current injector, such as an avalanche diode. The diode will conduct at a relatively low voltage, say 5 volts, providing sufficient erase current for a floating gate. One of the problems in adding a current injector is that substrate space is required in proximity to the floating gate. Such space can expand the foot print of a transistor memory cell which is contrary to the objective of creating a memory array with a very high density of memory cells.

An object of the invention is to provide an improved non-volatile memory array with memory cells using a single poly layer and which operates at relatively low voltage.

### SUMMARY OF INVENTION

The above object has been achieved in a memory architecture featuring an array of memory cells arranged in tic-tac-toe style quadrant with each cell utilizing a single poly layer for both a non-volatile memory transistor having a floating gate and a control transistor that are in series with each other. Low voltage programming and erasing is achieved by using a shared current injector at the center of the quadrant for charging and discharging the floating gate of the memory transistor. The shared injector is an implant that appears to be hidden in the sense that it occupies its own active area and not the active area of the floating gate transistor and the control transistor. A quadrant of four memory transistors in the memory array each has a floating gate with an extension that overlies the implant which operates as an avalanche diode for erasing an addressed memory transistor. Low voltage operation is achieved by using lumped distributed device capacitance to pull charge onto or from the floating gate. In other words, the floating gate is treated as one plate of a distributed device capacitor and diverse regions of the cell having electrical contacts form the other plate. External voltage applied to the electrical contacts can program the cell by pulling electrons from the floating gate, i.e. establishing holes on the floating gate, or erase the cell by placing electrons on the floating gate. The shared current injector is used at low voltage to provide ample hole or charge current to the floating gate.

### BRIEF DESCRIPTION OF THE DRAWINGS

FIG. 1 is a side sectional view of a non-volatile NOR memory cell in a memory array in accordance with the present invention.

FIG. 2 is a side sectional view of the memory cell in FIG. 1 illustrating capacitance coupling between a floating gate and device electrodes.

FIG. 3 is a side sectional view of a prior art avalanche gated diode employing a p+ implant in an n-well or in an n-type substrate.

FIG. 4 is a side sectional view of an avalanche gated diode with an n+ implant in a p-well or p-type substrate.

FIG. 5 is a side sectional view of an avalanche gated diode partially overlapping a floating gate in accordance with present invention.

FIG. 6 is a simplified top view layout of a single non-volatile NOR memory cell with a shared avalanche gated diode in a memory array in accordance with the present invention.

FIG. 7 is a top view of a plan for the active area of a portion of a memory array in accordance with the present invention with avalanche gated diodes shared among quadrants of four memory cells.

FIG. 8 is a top view of the memory array following the layout of FIG. 7, showing a half of a single quadrant of four memory cells with an overlay of the first polysilicon layer.

FIG. 9 is a side sectional view of the half quadrant of FIG. 8 taken along lines A-A of FIG. 8.

FIG. 10 is a top view of the memory array of FIG. 8 but with more than a full quadrant of memory cells.

FIG. 11 is a plot of gate current versus gate voltage for an N-MOS memory storage transistor.

FIG. 12 is a plot of gate current versus gate voltage for an avalanche injector in a P-MOS array cell in accordance with the present invention.

### BEST MODE FOR CARRYING OUT THE INVENTION

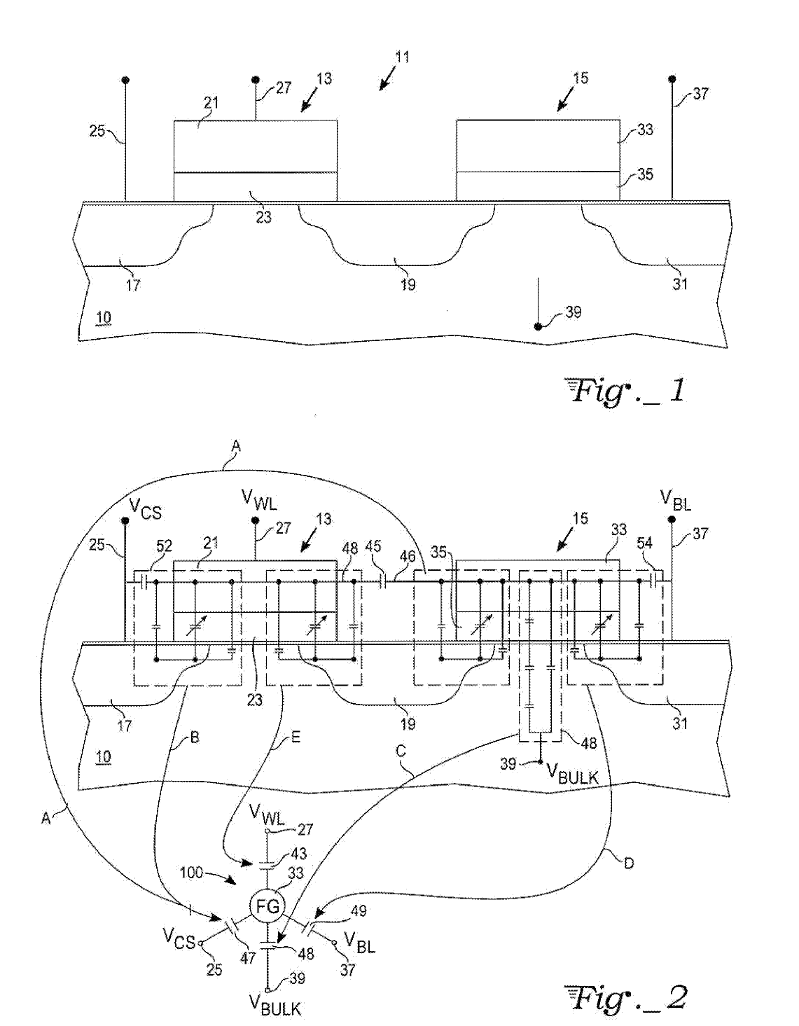

With reference to FIG. 1, a representative memory cell 11 is shown built in an active area of a semiconductor substrate 10 for a NOR non-volatile memory array. The memory cell features a control transistor 13 and a memory transistor 15 which is a non-volatile floating gate transistor. The control transistor 13 has a buried implant serving as a common source 17 with a common source electrode 25 which can control the voltage of the common source. The control transistor also has a shared drain 19 with a channel region between the common source 17 and the shared drain 19. A conductive polysilicon control gate 21 with a word line electrode 27 overlies insulative oxide layer 23 and the channel and slightly overlaps inward regions of common source 17 and shared drain 19. Control transistor 13 is seen to be spaced apart from floating gate transistor 15. The amount of spacing measured above the substrate is established by acceptable capacitance between gates 21 and 33. This dimension is important because floating gate transistor 15 relies upon capacitive coupling with the control transistor 13. Capacitive coupling cannot be achieved efficiently if the dimension is significantly greater or smaller than an optimum size.

The transistor 15 utilizes shared drain 19 and has an implanted source 31 which also serves as an array bitline, using bitline contact 37. An insulative oxide layer portion 35, having the same thickness a oxide layer portion 23, on the order of 50 Angstroms, overlies the channel region between shared drain 19 and source 31. Oxide thickness should be sufficient to insure good gate insulation but thin enough to allow electron and hole electric field transport when program and erase bias is applied, typically between 50-65 Angstroms. A polysilicon floating gate 33 overlies the oxide layer region 35 and has the same thickness as polysilicon control gate 21, typically between 500-700 Angstroms and preferably not exceeding 700 Angstroms, with both gates formed from the same polysilicon layer. The transistor substrate has a bulk contact 39 for helping to establish proper bias. This contact electrically communicates with an avalanche diode associated with the substrate and described below. Bias lines include the common source electrode 25, word line electrode 27, bitline contact 37 and the bulk contact 19. These four contacts are used to establish proper voltages for placing electrons or holes on the floating gate by means of lumped distributed device capacitance which is seen more clearly in FIG. 2. The term “distributed device capacitance” means inherent capacitance that arises without actual capacitors necessarily present, although such capacitors may be present.

With reference to FIG. 2, transistors 13 and 15 are seen with the same reference members as in FIG. 1. Distributed device capacitances have been drawn illustrating the capacitance between the floating gate 33 and all other transistor cell regions where capacitance exists, particularly capacitance associated with control transistor 13. A principal capacitance arises from the physical spacing of floating gate 33 and control gate 21. To a large extent the capacitance is determined by the spacing between the gates which is optionally feature size spacing, F, described above. This capacitance is represented by capacitor 45 having a lead 46 associated with floating gate 33 and a lead 48 associated with control gate 21. The dashed lines represent blocks of distributed device capacitance on each side of capacitor 45 and from one of the associated leads 48 or 48 to the oxide below the gate, to implants or regions below the oxide and to the substrate outside of the respective gate and underlying oxide. Common source electrode 25 is capacitively associated with block B through device capacitance indicated by capacitor 52. However, block B is partially offset or balanced by block A on the opposite side of capacitor 45.

It is significant to consider various capacitances in relation to floating gate 33 since charge is to be applied to and removed from the floating gate. Secondly, it is significant to consider various capacitances in relation to circuit locations where different voltages can be applied. Those locations are common source electrode 25 where V_{CS} is applied, word line electrode 27 where V_{WL} is applied, bitline 37 where V_{BL} is applied and bulk contact 39 where voltage and current from the neighboring avalanche diode appears, the voltage termed V_{BULK}.

Returning to floating gage 33 and the lead 46, some distributed device capacitance exists between lead 46 and the substrate 10 represented by block C where distributed device capacitance has bulk terminal 39 where the voltage V_{BULK} will appear.

Bitline 37 is slightly spaced from floating gate 33, the gap giving rise to capacitance 54 with one lead connected to bitline 37 and another lead joined to lead 46 of capacitor 45. The distributed device capacitance associated with capacitor 54 on lead 46 is represented by block D and controlled by the bitline voltage, V_{BL}. Lastly, the distributed device capacitance associated with lead 48 that is associated with word line electrode 27 is represented by block E. The various distributed device capacitance may be lumped wherein the blocks are represented by a single representative capacitor controlled by one of the voltages described above in a summary diagram below the memory cell.

Blocks A and B are combined because they are balanced and on opposite sides of capacitor 45, except block B is closed to common source electrode 25 which influences nearby lead 48. The lumped capacitance is capacitor 47 in the summary diagram 100. One side of capacitor 47 is associated with common source electrode 25. As mentioned above, the summary diagram 100 is a representation of the distributed device capacitances shown immediately above in the memory cell. The distributed device capacitance of block C is represented by capacitor 48 with bulk contact 39 influencing one side of the capacitor. The distributed device capacitance of block D is represented by capacitor 49 and controlled by bitline 37. Lastly, the distributed device capacitance of block E is represented by capacitor 43 and controlled by word line 27. Floating gate 33 is represented as a single common capacitor plate with a single electrical potential on lead 46. On the other hand, the other plate of the same capacitor is made up of leads, contacts or electrodes associated with voltages V_{WL}, V_{CS}, V_{BULK}, and V_{BL} applied at diverse cell locations. Therefore, to charge floating gate 33, the voltages V_{WL}, V_{CS}, V_{BULK}, and V_{BL} are set to draw holes or electrons onto the floating gate. No applied voltage exceeds 5 volts, more or less. The four voltages in combination exert a substantial electric field on the floating gate, causing sufficient electron or hole current onto the floating gate for a charging or erase operation. In erase and program operations the role of V_{BULK} is more significant as more substrate current is needed to place electrons and holes on the floating gate. In those operations, the associated avalanche diode becomes more significant as an influence on V_{BULK}.

In summary, the floating gate is seen as a common or shared plate relative to virtual plates. The common plate will have an induced charge equal and opposite to the charge on the aggregate of the virtual plates, a value established by the voltages on the voltage terminals, V_{CS}, V_{WL}, V_{BL}, and V_{BULK}. This is a way of charging and discharging a floating gate that does not depend upon high voltage for tunneling or go for charge injection.

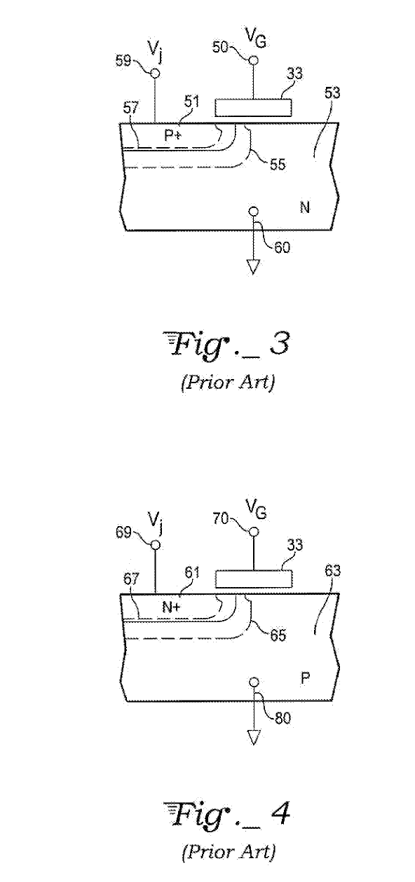

With reference to FIG. 3, prior art operation of an avalanche gated diode is shown. An n-well 53 exists in a substrate in which p+ implant 51 resides. Dashed lines 55 and 57 indicate depletion boundaries when reverse bias is applied, with the boundaries moving away from each other. Bias may be applied at terminal 59 and at substrate terminal 60. A pseudo-terminal 50 represents voltage, V_{G}, on the floating gate. The avalanche diode is represented by the junction between the p+ implant 51 and n-well 53.

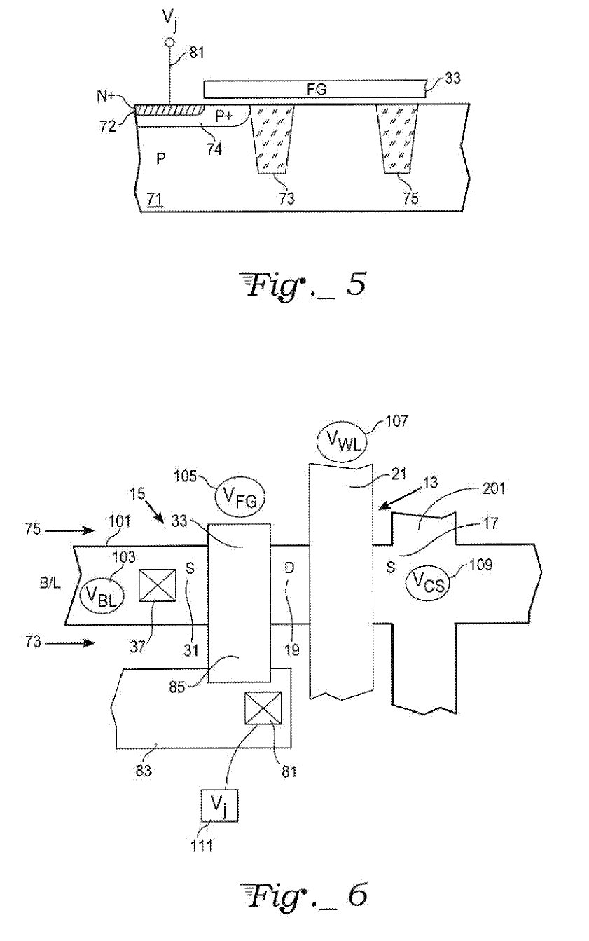

FIG. 4 is the same situation as FIG. 3 with polarities reversed. N+ implant 61 resides in p-well or p-substrate 63. Depletion boundaries 65 and 67 are analogous to depletion boundaries 55 and 57 of FIG. 3. Pseudo-terminal 70 measures the voltage, V_{G}, on floating gate 33 relative to the substrate terminal 80.

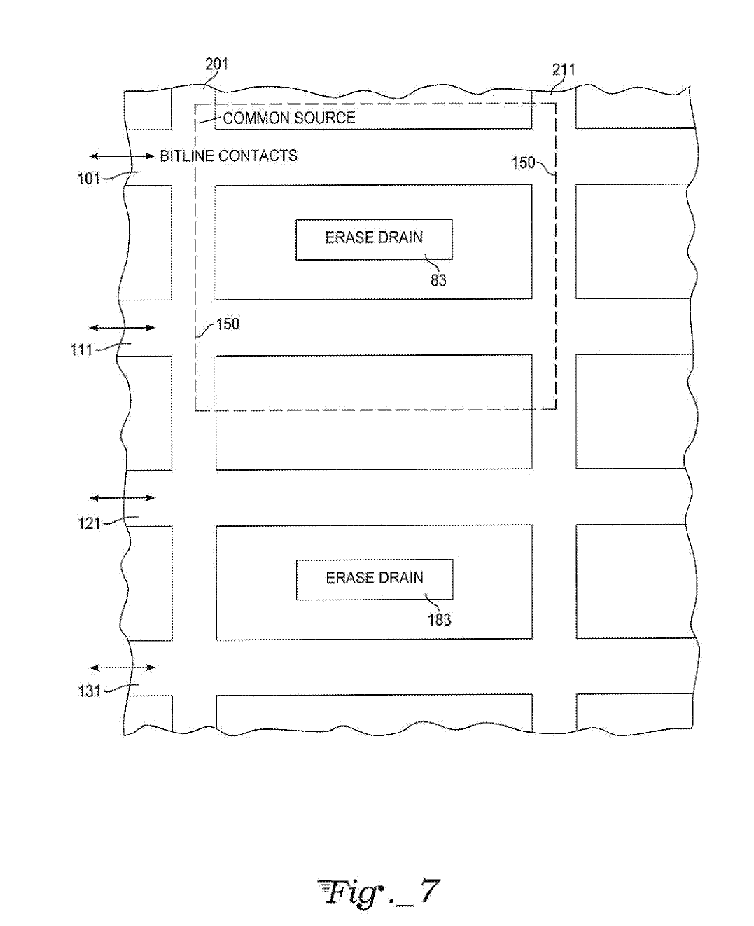

In FIG. 5, the shared avalanche diode injector in substrate 71 consists of a p+ implant 74, forming a p-well 74 receiving the n+ implant 72, having an electrode 81. The p+ implant 74 is in a p type substrate 71 having isolation barriers 73 and 75 to define a transistor region between the isolation regions. A floating gate region 33 of the transistor overlaps the avalanche diode and lies mainly between the isolation regions 73 and 75 of FIG. 5 where the transistor is built. The manner in which the avalanche diode is shared will be seen below. Note that the avalanche diode is in a different isolation region from source and drain of the transistor built between isolation regions 73 and 75.

With reference to FIG. 6, control transistor 13 is seen to be adjacent to memory transistor 15 in top view. A horizontal stripe 101 delineates an active area between isolation regions 73 and 75. Cell address voltages and bias on the floating gate are indicated by circles representing contacts except that the floating gate voltage V_{FG} has no contact. A contact 111 with bias Vⱼ is applied to the avalanche diode through and electrode 81 with contact into an implanted shared erase drain 83, yielding the reverse bias, V_{BULK}. This voltage appears in the shared erase drain region 83, in a separate isolation region from its memory cells. Above the substrate is a single layer of poly including floating gate 33 overlaps shared erase drain 83 at region 85. Transistor 15 has a source implant, S, in region 31 and a shared drain implant D in region 19. Transistor 13 also uses the shared rain D in region 19 and has a source implant S in region 17 that is part of a common source line 201. Source region 31 is associated with bitline voltage 103 applied through contact 37. The floating gate 33 is associated with floating gate voltage, V_{FG}, represented by circle 105, determined as explained with reference to FIG. 2. The control gate 21 is associated with wordline voltage of circle 107. Common source line 201 is associated with a common source voltage represented by circle 109. Contact 81 is associated with the bias applied to the avalanche diode, Vⱼ, indicated by contact 111.

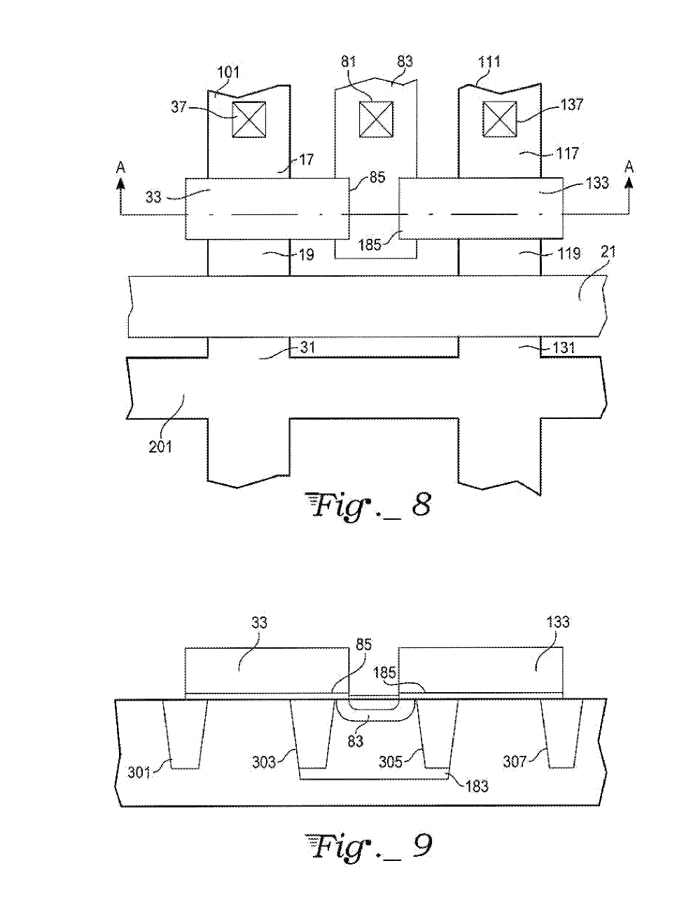

With reference to FIG. 7, the active area to be used by a memory array in accordance with the present invention is defined by field oxide whose boundaries are the lines that form the stripes shown. Principal features of the active area include the horizontal stripes 101, 111, 121 and 131 and vertical stripes 201 and 211 that establish a tic-tac-toe style pattern that is replicated vertically and horizontally to form the memory array. The horizontal stripes are for bitline contacts, as shown in FIG. 6. The stripes are well contained, having spaced apart source and drain implant regions that are self-aligned with polysilicon stripes, once the polysilicon layer is applied as a layer and etched to the desired patterns. Vertical stripes 201 and 211 are common source stripes. The vertical stripes 201 and 211 in combination with horizontal stripes 101 and 111 define a quadrant of four memory cells, described below, whose spatial extent is indicated by dashed line 150. Within the quadrant of cells is a single erase drain implant region 83, a region built in a separate isolation area and intended to be shared among the four cells that comprise the quadrant. Note that the next erase drain region 183 does not appear between active area stripes 111 and 121, but the next region appears between stripes 121 and 131. The reason for the lesser number of drain contacts relates to the direction of overlap of floating gates that permits four memory cells to share a single shared erase drain region. This may be seen more clearly in FIG. 8.

With reference to FIG. 8, one-half of a single memory array quadrant of FIG. 7 is shown, except that the drawing is rotated by 90 degrees. The half quadrant of FIG. 8 would have two memory cells, with each memory cell having two transistors, a floating gate transistor and a control transistor. Common source line 201 provides the source implant region 31 for the control transistor which utilizes the control gate 21, shown as a polysilicon stripe. The source implant region 31 is on a lower side of this stripe while a shared drain implant region 19 is in the substrate on an upper side of the stripe. Source 31 and shared drain 19 have a channel therebetween, directly under the control gate 21. Slightly spaced from the control gate stripe 21 is a first floating gate 33 with common source 17 opposite the shared drain 19. The space between the edges of the control gate stripe 21 and the first floating gate 13 is very important, as mentioned above, because it determines a significant amount of capacitive coupling between the control transistor and the memory transistor. This capacitance was represented as capacitor 45 in FIG. 2. F is the minimum available feature size, a dimension that depends upon the specific lithographic equipment being used, as mentioned above. Using that dimension, an overall cell area on the order of 25 F2 to 30 F2 (where F2 mean F squared) can be attained. Accordingly, a quadrant of four transistors would have a dimension on the order of 100 F2 to 120 F2. On the upper side of floating gate 33, a source implant 17 is established having a bitline contact 37 in bitline stripe 101. The active region associated with the bitline contact appears as the vertical stripe 101, a region established by isolation barriers.

Mirroring the two transistors on the left side of the drawing are two transistors on the right side. A control transistor has a source region 131 and an implant of shared drain region 119. Between the source and drain is the control gate 21 which is a poly layer above the substrate. The other poly region above the substrate for the second transistor cell is the floating gate 133 which is a counterpart of the first floating gate 33. Second floating gate 133 has the same dimensions as first floating gate 33 and is in a mirror image relationship to it having common source 117 opposite the shared drain 119. A bitline contact 137 makes contact with common source region 117 using bitline stripe 111 for electrical communication.

The first floating gate 33 and the second floating gate 133 have overlap regions 85 and 185 respectively, which overlie a shared erase drain 83. The shared erase drain 83 has a contact 81. Recall that the shared erase drain 83 will be used by four cells, although only two cells are shown in FIG. 8. The shared erase drain 83 is in an implant region.

With reference to FIG. 9, isolation regions 301 and 303 define a first isolation region associated with bitline stripe 101 of FIG. 8, while isolation regions 305 and 307 define an active area associated with bitline stripe 111. Floating gate 33 is seen servicing the left memory cell while floating gate 133 is seen servicing the right memory cell. Below the surface of the substrate is the shared erase drain 83, an implanted region in a well 183 that behaves as explained in reference to FIG. 5. Note that portions 85 and 185 of the floating gates 33 and 133 overlie the diode.

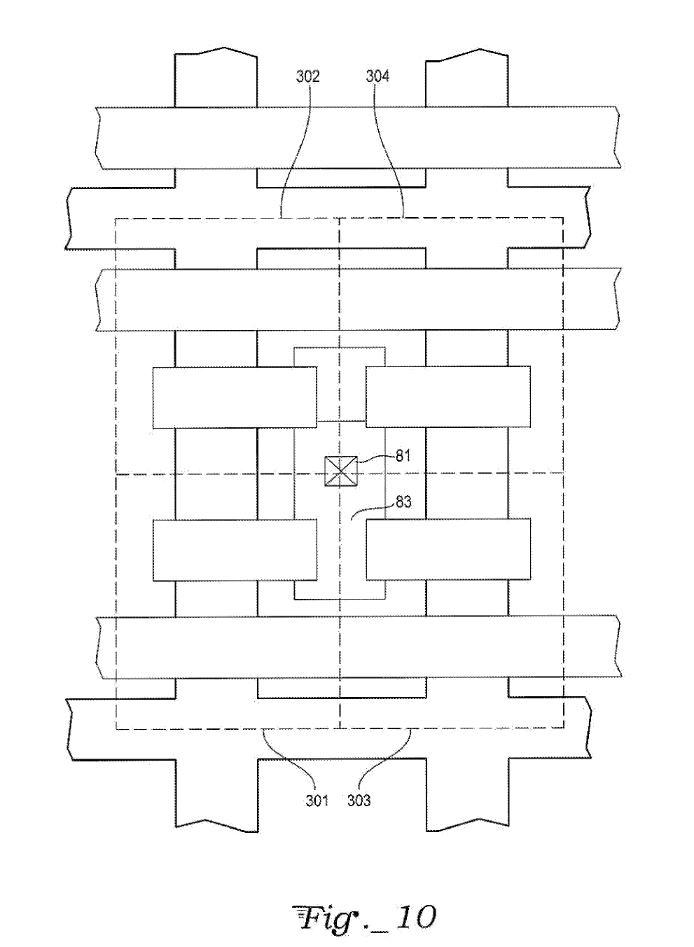

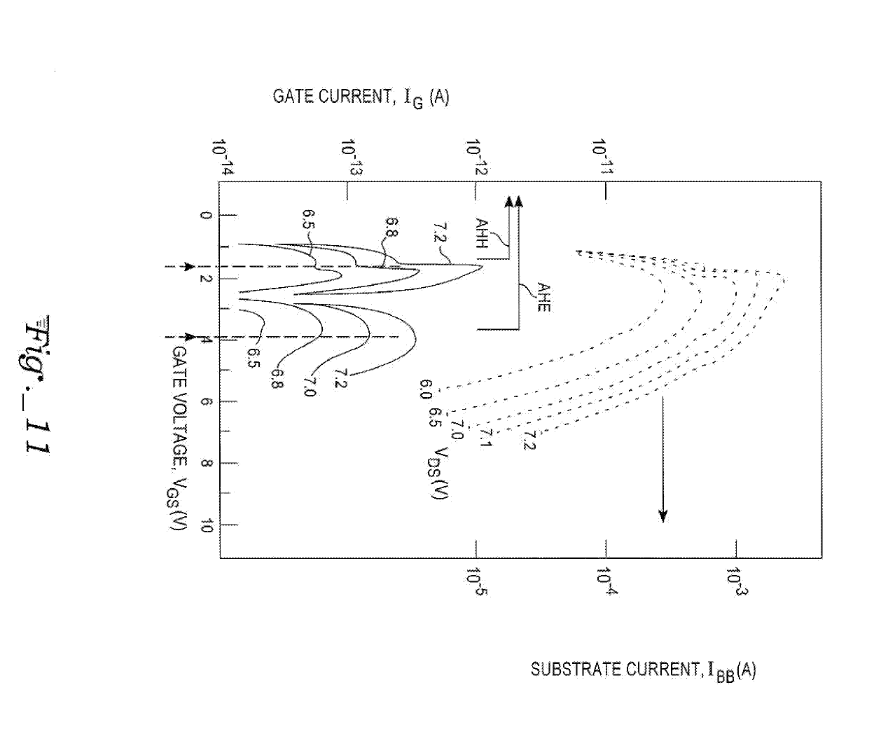

With reference to FIG. 10, a quadrant of four memory cells, indicated by dashed lines, use the shared erase contact 81. The transistor cells 301 and 303 are the same as shown in FIG. 8. These two cells are mirrored by cells 302 and 304 which also share the shared erase drain contact 83. The four memory cells are laterally and vertically symmetric with the two axes of symmetry crossing within the shared erase drain 83 and erase drain contact 81.

With reference to FIG. 11, the upper curves with dashed lines show substrate current from the avalanche diode for given drain-to-source voltages, V_{DS}, for a memory cell of the type shown in FIG. 6 when fabricated in an NMOS process. The lower curves with solid lines show gate current for hot holes (AHH) and hot electrons (AHE) for the same V_{DS} voltages shown above. The curves show that for a gate-to-source voltage, V_{DS}, equal to 1.5 V there is a peak of hot holes injected into the floating gate. For V_{GS} equal to 4 V there is a peak of electrons injected into the floating gate.

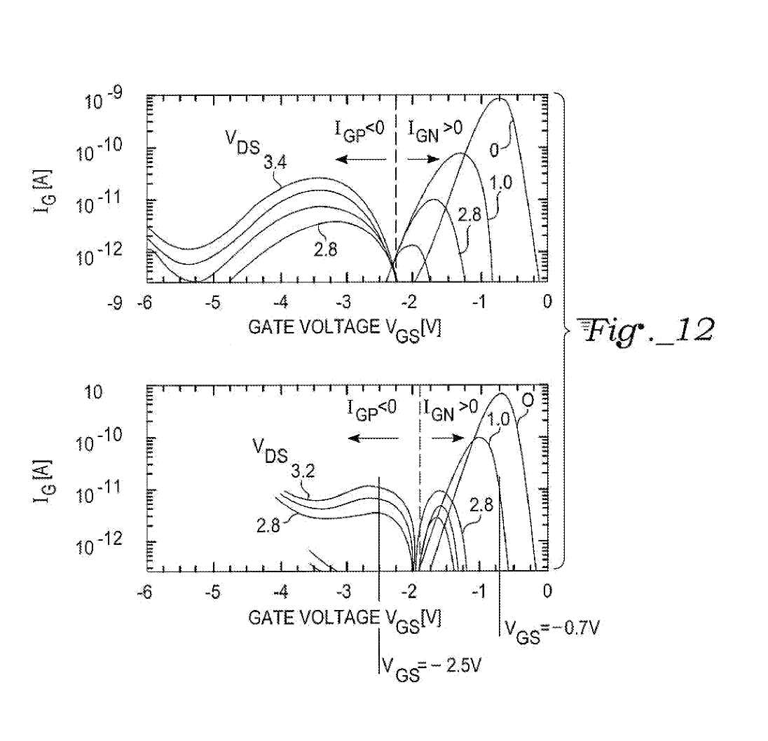

The curves of FIG. 12 are for a PMOS process. Here the curves reflect a dip in gate current to be avoided. The upper graph shows substrate current toward the floating gate. The lower graph shows substrate current into the floating gate. Electron current into the floating gate is a maximum at about −0.7 V. Maximum hole current is about at −2.5 V. These values are for transistor shaving an oxide thickness of 50 Angstroms and a width-to-length ratio W/L=500/0.5 μm.

What is claimed is:

1. A non-volatile transistor memory array comprising:
a plurality of memory cells in a semiconductor substrate each memory cell including a floating memory transistor spaced apart and capacitively coupled to a control transistor, the capacitive coupling influenced by distributed device capacitance therebetween;
a floating gate of the floating gate memory transistor acting as a first plate of a capacitor and a plurality of electrical contacts to diverse regions of the memory cell including among the diverse regions a control gate of the control transistor acting as a second plate, a wordline and a bitline being two of the electrical contacts with a bulk node being a third contact; and
an avalanche diode having a first terminal in electrical communication with said third contact and a second terminal having a terminal external to the memory cell whereby bias applied through the electrical contacts programs and erases the floating gate.

2. The memory array of claim 1 wherein the memory cell has substrate portions in a first active area of the semiconductor substrate and the avalanche diode is in a second active area, spaced apart from the first active region, with the floating gate having portions extending over both the first and second areas.

3. The memory array of claim 1 wherein the control transistor and the floating gate memory transistor share a common substrate source-drain region.

4. The memory array of claim 1, wherein the floating gate of the floating gate memory transistor and the control gate of the control transistor are polysilicon having a thickness not exceeding 700 Angstroms.

5. The memory array of claim 1 wherein the memory cells are arranged in a quadrant defined by active areas of the substrate.

6. The memory array of claim 5 wherein the quadrant has a central zone not occupied by active areas associated with memory cells, the central zone having an avalanche diode active area.

7. The memory array of claim 6 wherein each floating gate of each memory cell has a portion extending partly over the avalanche diode active area.

8. The memory array of claim 1 wherein each memory cell has a control transistor with a conductive gate connected to the wordline.

9. The memory array of claim 1 wherein each memory cell has a source-drain electrode connected as a common source line for a plurality of memory cells.

10. The memory array of claim 1 wherein each memory cell has a floating gate electrode with a source-drain electrode connected as a bitline.

11. The memory array of claim 5 wherein the memory cells are laterally mirrored across the quadrant.

12. The memory array of claim 5 wherein the memory cells are vertically mirrored across the quadrant.

13. A non-volatile transistor memory array comprising:
a plurality of memory cells, each cell built in a cell active area of a semiconductor substrate having a non-volatile floating gate memory transistor in a shared subsurface electrode relation with a control transistor; and
an erase drain implant region in a separate active area from the cell active area, the memory transistor communicating with the erase drain implant region by the floating gate of the memory transistor partially overlying the erase drain implant.

14. The array of claim 13 wherein the floating gate and control transistors each having a single poly layer.

15. The array of claim 13 wherein a plurality of floating gates of a plurality of memory transistors of the array overlay one erase drain implant.

16. The memory array of claim 15 wherein the number of floating gates that overlay one erase drain implant is four.

17. The memory array of claim 13 wherein the control transistor has a common source electrode for at least a portion of the array, the source electrode being spaced apart from the shared subsurface electrode.

18. A non-volatile transistor memory array comprising:
quadrants of a plurality of non-volatile memory cells arranged in a rectangular array of rows and columns on a semiconductor substrate, each quadrant of memory cells groups around an avalanche diode region implanted in the substrate, each memory cell having a floating gate transistor with a poly region overlapping the diode region wherein the diode region is shared by the four non-volatile memory cells.

19. The memory array of claim 18 wherein each memory cell comprises a floating gate transistor and a control transistor.

20. The memory array of claim 18 wherein each quadrant of memory cells comprises a group of four memory cells.
